(19) United States
(12) Patent Application Publication
(10) Pub. No.: US 2008/0008640 A1
(43) Pub. Date: Jan. 10, 2008

(54) Cluster-Free Amorphous Silicon Film, and Method and Apparatus for Producing the Same

(76) Inventors: Yukio Watanabe, Fukuoka-shi (JP); Masaharu Shiratani, Fukuoka-shi (JP); Kazunori Koga, Fukuoka-shi (JP)

Correspondence Address: JORDAN AND HAMBURG LLP, 122 EAST 42ND STREET, SUITE 4000, NEW YORK, NY, 10168, US

(21) Appl. No.: 11/661,053

(22) PCT Filed: Aug. 17, 2005
(86) PCT No.: PCT/JP05/15007

§ 371 Date: Apr. 4, 2007

(30) Foreign Application Priority Data
Aug. 24, 2004 (JP) 2004-244333

(51) Int. Cl. H01L 21/205; C01B 33/027; H01L 31/04; C23C 16/24

(52) U.S. Cl. 423/324; 106/287.1; 118/50.1; 427/578

(57) ABSTRACT

The intention is to clarify characteristics of a cluster-free amorphous silicon film which is practically produceable without incorporation of large clusters having a size of 1 nm or more, and provide a method and an apparatus for producing the amorphous silicon film. In the cluster-free amorphous silicone (a-Si:H) film, an in-film Si—H₂ bond density is 10⁻² atomic % or less, and an in-film volume fraction of the large clusters is 10⁻¹% or less. The a-Si:H film is produced by depositing, on a substrate, a deposition material in a plasma flow of any one of a silane gas, a disilane gas and a gas obtained by diluting a silane or disilane gas with one or a combination of two or more selected from the group consisting of hydrogen, Ar, He, Ne and Xe. The a-Si:H film has prominent characteristics, such that: a light-induced defect density is reduced from 2×10¹⁶ cm⁻³ or more in conventional a-Si:H films to substantially zero; a stabilized efficiency (%), i.e., a light-energy conversion efficiency, is increased from 9% at the highest in existing a-Si:H films up to 14% or more; and a light-induced degradation rate, i.e., [(initial efficiency−stabilized efficiency)/initial efficiency]×100%, is reduced from 20% at the lowest in the existing a-Si:H films to substantially zero.

### TECHNICAL FIELD

The present invention relates to a cluster-free amorphous silicon film which is free from large clusters having a size of 1 nm or more, and the production of the amorphous silicon film.

### BACKGROUND ART

It is the highest priority issue in the 21st century to solve problems of expanding energy consumption and environmental destruction arising from economic development and population growth (so-called “trilemma”). Photovoltaic power generation is expected to play a large role in solving the problems, and therefore solar cells are needed to achieve higher efficiency and lower cost.

Heretofore, an amorphous silicon (hereinafter referred to as “a-Si:H”) thin film for use in a photoelectric conversion element for solar cells has been deposited, for example, in the following manner. A pair of flat-plate electrodes are disposed parallel to each other in a vacuum vessel, and a substrate is held by one of the flat-plate electrodes. After a silane gas is supplied into the vacuum vessel to set a desired degree of vacuum therein, a high-frequency power is fed to the other flat-plate electrode in opposed relation to the substrate-holding flat-plate electrode to generate a capacitively-coupled high-frequency discharge plasma, whereby an amorphous silicon thin film is deposited on a surface of the substrate. While the solar cell using an a-Si:H thin film is expected as a core of power-generating solar cells, light-induced degradation in an a-Si:H thin film deposited at a high rate remains as a long-standing major problem to be solved.

In this context, it was recently pointed out that Si microparticles (Si clusters) with a size about 10 nm or less, which are generated in a silane plasma used in depositing a-Si:H film, are likely to have a close relation to the light-induced degradation (see the following Non-Patent Publication 1). From this standpoint, a key to solving to the light-induced degradation problem is to clarify a growth mechanism of the Si clusters and quantitatively define a relationship between an amount of Si clusters to be incorporated in an a-Si:H film, and properties of the film, so as to develop a process of depositing a high-quality a-Si:H film at a high rate while suppressing Si clusters causing film degradation, based on the obtained knowledge.

In view of the above approach, based on a newly-developed on-site measurement technique for Si clusters, the inventors of this application clarified the growth mechanism of Si clusters in a silane plasma, and the relationship between growth suppression of Si clusters and a deposited film, in the Non-Patent Publication 1. Specifically, the inventors obtained experimental data showing that small clusters (about 0.5 nm), large clusters (about 1 to 10 nm) and particles (about 10 nm or more) coexist in a silane plasma during a nucleus formation stage, and the large clusters will grow with time, wherein the large cluster is mainly composed of a particle with an amorphous structure which comprises a primary component of silicon.

The deposition of a-Si:H on the substrate according to a silane gas plasma is caused by the following primary reaction.

[Primary Reaction]
SiH₄+e→SiH₃+H+e (minimum electron energy: 8.75 eV)
SiH₄+e→SiH₂+H₂+e (minimum electron energy: 9.47 eV)
SiH₄+e→SiH+H₂+H+e
SiH₄+e→Si+2H₂+e

Further, the formation of a nucleus which will grow into a large cluster is primarily caused by creation and accumulation of a higher-order silane SiₓHₙ (x<5) based on the following secondary reaction.

[Secondary Reaction]
SiH₂+SiH₄→Si₂H₆
SiH₂+Si₂H₆→Si₃H₈
SiH₂+Si₃H₈→Si₄H₁₀

The Non-Patent Publication 1 further shows that a technique of combining respective effects of discharge modulation, electrode heating, gas flow and hydrogen radicals to suppress the growth of Si clusters has great potential as an effective measure. In a prototype solar cell using an a-Si:H thin film deposited through a Si-cluster-controlling plasma CVD process developed by the inventors (see the following Patent Publication 1), although a relatively high stabilized efficiency of 9% (equivalent to 2×10¹⁶ cm⁻³ in a light-induced defect density of this a-Si:H film) is obtained, a light-induced degradation phenomenon considered as a problem still occurs. In this respect, the plasma CVD process disclosed in the Patent Publication 1 has not reached a radical solution. The term “light-induced defect density” means a density of defects (unpaired electrons) in an a-Si:H film which are measureable by an electron spin resonance method, and newly developed due to irradiation of light having a spectrum and an intensity equivalent to those of solar light on earth.

As another technique of suppressing the incorporation of Si clusters in an a-Si:H thin film, the following Patent Publication 2 discloses a plasma treatment method of decomposing and reducing Si clusters generated in a plasma creation region while suppressing thermal deformation of a substrate and electrodes due to heating. Specifically, the plasma treatment method is intended for use with an apparatus designed such that a flat electrode and a substrate supported by an earth electrode connected to the ground is disposed in a face-to-face arrangement within a vacuum chamber supplied with a gas containing a deposition material. In the plasma treatment method, a high-frequency power generated by a high-frequency power feeder circuit is fed to the flat electrode to create a plasma between the flat electrode and the substrate so as to treat the deposition material, wherein a laser light is emitted to a plasma creation region to decompose Si clusters generated together with the plasma by energy of the laser light. Even in an a-Si:H thin film obtained by this method, a defect density is about 10¹⁵ cm⁻³ (this value is assumed to be an initial defect density, and equivalent to a light-induced defect density of about 2×10¹⁶ cm⁻³). As above, at present, there is no a-Si:H thin film having a light-induced defect density of less than 2×10¹⁶ cm⁻³. Thus, it is still awaited to clarify the relationship between Si clusters incorporated in an a-Si:H thin film and the light-induced degradation phenomenon.

[Patent Publication 1] JP 2002-299266 A

[Patent Publication 2] JP 2004-146734 A

[Non-Patent Publication 1] SHIRATANI, et al., “Growth Mechanism of Microparticles in Low-Pressure Silane Plasma”, School of Material Science, Japan Advanced Institute of Science and Technology, Summaries of 2001 1st School Forum “Basics and Applications of Silane-based CVD Process”, March/2002, p. 13-18

### DISCLOSURE OF THE INVENTION

### Problem to be Solved by the Invention

It is an object of the present invention to provide a cluster-free a-Si:H thin film which is practically produceable. It is another object of the present invention to clarify an upper limit of each film property achievable by Si-cluster suppression, and characteristics of a super-high-quality a-Si:H thin film obtained by the Si-cluster suppression. It is still another object of the present invention to figure out a further quantitative relation between an amount of large clusters incorporated in an a-Si:H thin film and properties of the film, while identifying a Si-cluster size having an impact on the film properties, and clarify a formation mechanism of nuclei of microparticles, so as to contribute to establishment of mass production techniques for a solar cell using a high-efficiency a-Si:H thin film free of light-induced degradation.

### Means for Solving the Problem

A cluster-free a-Si:H film of the present invention is characterized in that an in-film Si—H₂ bond density is 10⁻² atomic % or less, and an in-film volume fraction of large clusters is 10⁻¹% or less. The term “in-film Si—H₂ bond density” means a ratio of H₂-bonded Si atoms to the entire Si atoms in an a-Si:H film, and the in-film Si—H₂ bond density is proportional to an integrated intensity of an absorption spectrum component having a maximum absorption intensity around 2100 cm⁻¹ in an infrared absorption spectrum of the a-Si:H film. These numerical values are measurement results obtained by a FTIR (Fourier transform infrared spectroscopy) and an ESR (electron spin resonance) method. In a-Si:H films based on conventional film-depositing techniques, the Si—H₂ bond density and the volume fraction of large clusters have been 10⁻¹ atomic % and 2×10⁻¹% at best, respectively.

The cluster-free a-Si:H film of the present invention is produced by depositing, on a Si or glass substrate, a plasma flow of a silane gas or a disilane gas. Thus, the a-Si:H film (referred to occasionally as “Si film”), has prominent characteristics, such that: a light-induced defect density is reduced from 2×10¹⁶ cm⁻³ or more in conventional Si films to substantially zero, specifically, a value equal to or less than a detection sensitivity (3×10¹⁴ or less) of a detector; a stabilized efficiency (%), i.e., a light-energy conversion efficiency, is increased from 9% at the highest in existing Si films up to 14% or more; and a light-induced degradation rate, i.e., [(initial efficiency−stabilized efficiency)/initial efficiency]×100%, is reduced from 20% at the lowest in the existing Si films to substantially zero, specifically, a value equal to or less than a detection sensitivity (2% or less) of a detector.

The above cluster-free a-Si:H film is obtained by preventing large clusters from being incorporated in an a-Si:H film to be deposited, by means of suppressing the generation itself of large clusters, or removing generated large clusters, or a combining them. The first means for suppressing the generation itself of large clusters may include a technique of controlling an electron energy distribution in a VHF discharge, and a technique of diluting a discharge atmosphere with one or a combination of two or more selected from the group consisting of H₂, Ar, He, Ne and Xe. The second means for removing generated large clusters may include a technique of removing generated large clusters from a discharge region by use of a gas flow-induced viscous force, a technique using a thermophoretic force (i.e., thermal migration force) based on a temperature gradient, a technique of exerting an electrostatic force, a technique of eliminating a gas stagnation region, and a technique of applying a repetitive on-off discharge and removing generated large clusters during the OFF period. In particular, large clusters with a size of several nm or more can be approximately fully removed from a discharge region by means of the thermophoretic force based on a temperature gradient. The incorporation of large clusters can be suppressed by means of the repetitive pulsed discharge, to an undetectable level even by an ultrasensitive photon-counting laser scattering method. Further, a filter for removing large clusters may be additionally provided so as to prevent large clusters from being incorporated in an a-Si:H film during deposition of silane plasma onto the substrate.

### Effect of the Invention

The cluster-free a-Si:H film of the present invention has prominent characteristics which are not an extension of those of the conventional Si cluster-reduced a-Si:H film, and can eliminate 90% or more of large clusters which have existed in the conventional a-Si:H film, by low-cost means without lowering a film-deposition rate.

### BEST MODE FOR CARRYING OUT THE INVENTION

The present invention will now be described based on an embodiment thereof where an a-Si:H film is deposited using a silane gas.

### First Embodiment

In a first embodiment of the present invention, a technique of increasing a gas flow rate in a plasma region, generating a thermophoretic force which acts on large clusters in gaseous phase, and capturing large clusters by an inner wall of a hole to remove the large clusters is used for preventing the incorporation of large clusters in an a-Si:H film to be deposited. FIG. 1 shows an amorphous silicon thin film deposition apparatus 10 (hereinafter referred to simply as apparatus 10″) using the above technique. As shown in FIG. 1, the apparatus 10 comprises a cylindrical-shaped reaction chamber (vacuum chamber) 11, a substrate holder 13 attached to a bottom of the reaction chamber 11 and provided with a gas inlet pipe 12, and a vacuum pump 19 connected to a top of the reaction chamber 11. A pair of perforated earth electrodes 14a, 14b and a perforated high-frequency electrode 15 are disposed parallel to each other within the reaction chamber 11, and a gas is directed to flow in a direction perpendicular to each surface of these electrodes. Each of the perforated high-frequency electrode 15 and the perforated earth electrodes 14a, 14b is formed with a plurality of through-holes 16 each having a diameter of 2 to 3 mm and a length of 5 to 10 mm, and the apparatus 10 is adapted to create a plasma in these through-holes 16 of the electrodes. Thus, each of the through-holes 16 having a relatively small sectional area allows the gas to flow through the through-holes 16 at a high flow rate of about 20 to 200 cm/s, so as to exert a gas flow-induced viscous force on large clusters to prevent the large clusters from being mixed or incorporated in a deposited film on the substrate. Further, the perforated high-frequency electrode 15 is maintained at a temperature of about 150° C., while maintaining the perforated earth electrode 14a at a temperature of about 50° C. according to a water-cooling control, to generate a temperature gradient of 300 K/cm, so as to exert a thermophoretic force on the large clusters to further reliably prevent large clusters from being mixed or incorporated in a deposited film on the substrate 17. A distance between the perforated high-frequency electrode 15 and the perforated earth electrode 14a is set at an extremely small value of about 1 mm. This makes it possible to readily generate a significantly large temperature gradient between the two electrodes. Typically, conventional amorphous silicon thin film deposition apparatuses are designed to set an inter-electrode distance at a relatively large value of about 20 mm, and thereby can achieve a relatively small temperature gradient of about 20 K/cm.

FIG. 2 shows a relationship between a thermophoretic force to be exerted on large clusters in gaseous phase based on an inter-electrode temperature gradient, and a diffusion force of large clusters in a deposited film. As seen in FIG. 2, while the diffusion force of large clusters in a deposited film is approximately constant irrespective of a particle size of large clusters, the thermophoretic force to be exerted on large clusters in gaseous phase based on an inter-electrode temperature gradient becomes higher as the particle size of large clusters becomes larger. Further, when the temperature gradient is 200 K/cm or more, the thermophoretic force to be exerted on migration of large clusters having a size of 1 nm or more becomes greater than the diffusion force of the large clusters. This means that the incorporation of large clusters in an a-Si:H thin film, which has adverse effects on characteristics of the thin film, is precluded by the thermophoretic force. When the temperature gradient is 100 K/cm or less, the diffusion force of large clusters having a size of about 1 to 2 nm becomes greater than the thermophoretic force to be exerted on the large clusters, and thereby such large clusters cannot be removed.

In an actual example using the apparatus 10 illustrated in FIG. 1, an internal pressure of the reaction chamber 11 was kept at 0.07 Torr by introducing a silane gas at a flow volume of 50 cm³/s from a gas inlet port 12a of the gas inlet pipe 12 into the reaction chamber 11 and simultaneously discharging the silane gas from the reaction chamber 11 by the vacuum pump 19. Further, a high-frequency power feeder circuit 18 including a high-frequency power source, a matching power source and a decoupling capacitor was operated to feed 5W of VHF power having a frequency of 60 MHz between the electrodes, so as to create a plasma primarily in each of the through-holes 16 of the electrodes. After the silane gas was supplied for 30 minutes, an a-Si:H thin film having a thickness of 500 nm was deposited on the substrate 17 kept at 250° C. Preferably, conditions for depositing an a-Si:H thin film using the apparatus 10 illustrated in FIG. 1 are set as follows: a flow volume of the silane gas is set in the range of 10 to 50 cm³/s (more preferably, 10 to 20 cm³/s); a flow volume of a hydrogen gas for diluting the silane gas is set in the range of 40 to zero cm³/s (more preferably, 40 to 30 cm³/s); and a total gas flow volume is set at 50 cm³/s (constant). Further, preferably, the inner pressure of the reaction chamber 11 is set in the range of 0.07 to 2 Torr (more preferably, 0.5 to 1 Torr); the VHF power to be fed between the electrodes is set in the range of 5 to 90 W (more preferably, 3 to 30 W); and the thickness of the a-Si:H thin film to be deposited is set in the range of 500 to 2000 nm.

As described above, in this embodiment, the incorporation of large clusters in a deposited film on the substrate is prevented based on the high-speed gas flow and the thermophoretic force in the through-holes 16, and the large clusters are captured and removed by the inner walls of the through-holes 16. FIG. 3 shows a relationship between a radius of the through-hole and a large-cluster removal rate (theoretical value). In view of the large-cluster removal rate, the radius of the through-hole is preferably set at a smaller value.

FIG. 4 shows characteristics of an a-Si:H thin film of the present invention deposited by preventing the incorporation of large clusters therein based on the aforementioned techniques, together with comparative examples. The power generation efficiency on the axis shown on the right side of FIG. 4 is a simulation value obtained based on the defect density. In FIG. 4, a white-square mark indicates measurement data of an a-Si:H thin film (according to the first embodiment) of the present invention, and a black circle mark indicates measurement data of an a-Si:H thin film (according to an after-mentioned second embodiment) of the present invention. The a-Si:H thin films of the present invention was measured by a FTIR method. As the result, the in-film Si—H₂ bond density was substantially zero atomic % (10⁻² atomic % or less), and the in-film large-cluster volume fraction was 10⁻¹% or less. The a-Si:H thin films having a temperature maintained at 60° C. were subjected to light irradiation at a light intensity of 2.4 sun for 10 hours, while measuring the defect density by an ESR method. As the result, the defect density was maintained at a constant value throughout the measurement, and the lowering rate of a power generation efficiency due to the light-induced degradation, represented by [(initial efficiency−stabilized efficiency)/initial efficiency]×100%, was maintained at zero %, which verified a prominent suability of the a-Si:H thin films.

In FIG. 4, a white circle mark indicates measurement data of an a-Si:H thin film deposited without using the large-cluster removal techniques. As seen in this curve, the lowest value of the in-film light-induced defect density in the thin film obtained by the conventional technique was ultimately about 2×10¹⁶ cm⁻³ at best. The in-film light-induced defect density will never become zero even if the curve is extrapolatively extended. Further, the lowest value of the in-film Si—H₂ bond density was about 10⁻¹ atomic %, and the highest value of the stabilized efficiency was about 10% at best.

FIG. 5 shows a light-irradiation-time dependence of an in-film defect density. In FIG. 5, a white square mark measurement data of an a-Si:H thin film (according to the first embodiment) of the present invention, and a black circle mark indicates measurement data of an a-Si:H thin film (according to the after-mentioned second embodiment) of the present invention. Further, a white circle mark indicates measurement data of an a-Si:H thin film deposited without using the large-cluster removal techniques. While the defect density was increased by one digit in the thin film obtained by the conventional technique, no increase in the defect density was observed the thin films of the present invention.

FIG. 6 shows respective in-film Si—H₂ bond densities in two a-Si:H thin films which have been deposited, respectively, on upstream and downstream sides of the perforated high-frequency electrode in the apparatus illustrated in FIG. 1. Large clusters generated within the perforated high-frequency electrode of the apparatus illustrated in FIG. 1 are removed toward a downstream side of the perforated high-frequency electrode by the gas flow. Thus, the large clusters were not incorporated in an a-Si:H thin film deposited on an upstream side of the perforated high-frequency electrode, and therefore this thin film had a significantly low in-film Si—H₂ bond density. In contrast, the large clusters were incorporated in an a-Si:H thin film deposited on the upstream side of the perforated high-frequency electrode, and this thin film had a high in-film Si—H₂ bond density of 1 atomic %, which is approximately the same level as those of conventional a-Si:H thin films. For this reason, in the apparatus illustrated in FIG. 1, the substrate for allowing an a-Si:H thin film to be deposited thereon is disposed on the upstream side of the perforated high-frequency electrode.

The technique according to the first embodiment makes it possible to facilitate increasing a film-depositing area so as to achieve a high film-deposition rate of 1 nm/s or more.

### Second Embodiment

In a second embodiment of the present invention, a cluster removal filter is used as one of large-cluster removal means. FIG. 7 shows an amorphous silicon thin film deposition apparatus 20 (hereinafter referred to simply as “apparatus 20”) using a cluster removal filter 21 as one of the large-cluster removal means. In this apparatus 20, a mesh-shaped high-frequency electrode 22, a mesh-shaped earth electrode 23 and a substrate 24 are disposed in a face-to-face arrangement within a reaction chamber (vacuum chamber) 25, and the cluster removal filter 21 is arranged immediately below the earth electrode 23. The mesh-shaped high-frequency electrode 22 and the mesh-shaped earth electrode 23 are disposed parallel to each other, and gas is directed to flow in a direction perpendicular to each surface of the electrodes. The substrate 24 may be made of Si, glass, stainless steel or polymer.

As shown in FIG. 7, the cluster removal filter 21 is arranged in a space through which a plasma generated between the two electrodes reaches the substrate 24 so as to prevent large clusters generated in the plasma from being incorporated in a deposited thin film on the substrate 24. The cluster removal filter 21 comprises two grid plates 21a, 21b, which are disposed in spaced-apart relation to each other by a distance equal to or less that a mean free path of a large cluster C and a SiH₃ radical R as a film precursor, while avoiding overlapping of their holes, to have an opening ratio of 50% or less in their entirety. Preferably, the distance between the two grid plates 21a, 21b is set to be approximately equal to or less that a mean free path (1 mm) of the large cluster C and the SiH₃ radical R as a film precursor. A filter reflection coefficient for the SiH₃ radicals R contributing to film deposition is 70%, and a filter reflection coefficient for the large clusters C is zero %. That is, the cluster removal filter 21 is adapted to remove only the large clusters C. FIG. 8 shows a relationship between a permeability rate of each of the grid plates of the cluster removal filter and a large-cluster removal rate.

In an actual example using the apparatus 20 illustrated in FIG. 7, an internal pressure of a reaction chamber 25 was kept at 0.07 Torr by introducing a silane gas at a flow volume of 30 cm³/s from a gas inlet pipe 26 into the reaction chamber 25 and simultaneously discharging the silane gas from the reaction chamber 25 by a vacuum pump 27. Further, a high-frequency power feeder circuit 28 was operated to feed 2 to 7W of VHF power having a frequency of 60 MHz between the electrodes, so as to create a plasma. Then, an a-Si:H thin film was deposited on a substrate 24 heated and kept at 250° C., for 10 hours. In this process, the cluster removal filter 21 disposed between the plasma and the substrate 24 functioned to prevent large clusters generated in the plasma from being incorporated in the deposited thin film on the substrate 24.

An a-Si:H thin film deposited in the above manner had characteristics equivalent to those in the first embodiment, as indicated by black circle marks in FIGS. 4 and 5. The black circle marks A, B and C in FIG. 4 indicate measurement data of a-Si:H thin films deposited under the conditions that the VHF power to be fed between the electrodes was set at 2W, 5W and 7W, respectively.

In the second embodiment, a plurality of the cluster removal filters may be arranged in a superimposed manner so as to maximally reduce the incorporation of large clusters in an a-Si:H thin film to be deposited.

### Third Embodiment

In a third embodiment of the present invention, a gas curtain (high-speed silane gas flow) is used as one of the large-cluster removal means, and employed in an amorphous silicon thin film deposition apparatus 30 (hereinafter referred to simply as “apparatus 30”) illustrated in FIG. 9 to produce a cluster-free a-Si:H film of the present invention. The apparatus 30 illustrated in FIG. 9 comprises a reaction chamber (vacuum chamber) 31 which houses a high-frequency electrode 32, an earth electrode 33 provided with a built-in heater and disposed in vertically opposed relation to the high-frequency electrode 32, and a substrate 34 adapted to allow an a-Si:H thin film to be deposited thereon and placed on the earth electrode 33. The apparatus 30 is designed to feed a high-frequency power generated by a high-frequency power feeder circuit (not shown) to the high-frequency electrode 32 to create a plasma in a silane gas introduced between the high-frequency electrode 32 and the earth electrode 33 so as to deposit Si on the substrate 34 to deposit an a-Si:H film.

In this embodiment, the high-frequency power feeder circuit is designed to feed 2W of VHF power having a frequency of 60 MHz, to the high-frequency electrode 32, to create a plasma. Further, first and second silane gas inlet ports 35, 36 are provided in one of opposite lateral walls of the reaction chamber 31 in vertically space-apart relation to each other, and first and second vacuum pumps 37, 38 are provided in the other lateral wall at respective positions corresponding to the first and second silane gas inlet ports, in such a manner that a low-speed gas flow “a” is formed between the high-frequency electrode 32 and the earth electrode 33 and on the side of the high-frequency electrode 32, and a high-speed gas flow “b” is formed between the high-frequency electrode 32 and the earth electrode 33 and on the side of the earth electrode 33. Specifically, a silane gas is introduced from the silane gas inlet ports 35 while discharging the silane gas through the vacuum pump 37, so as to set a flow rate of the low-speed gas flow “a”, at about 1 to 10 cm/s. Further, a silane gas is introduced from the silane gas inlet ports 36 while discharging the silane gas through the vacuum pump 38, so as to set a flow rate of the high-speed gas flow “b” immediately above the substrate 34, at about 20 to 100 cm/s. More specifically, the flow rate of the high-speed gas flow “b” immediately above the substrate 34 is set at a value greater than an in-film diffusion rate (about 10 cm/s) of large clusters and less than a diffusion rate (about 200 cm/s) of SiH₃ radicals as a film precursor. In conventional film depositing techniques, a set of a gas inlet port and a vacuum pump are provided, and a gas flow rate is typically set at 5 cm/s.

In this embodiment, a viscous force induced by the high-speed gas flow “b” immediately above the substrate 34 is exerted on large clusters so as to prevent the large clusters from being incorporated in a deposited thin film on the substrate 34. In other words, the high-speed gas flow “b” immediately above the substrate 34 acts as a large-cluster removing gas curtain so as to prevent large clusters from being incorporated in a deposited thin film on the substrate 34.

An a-Si:H thin film deposited in the above manner had characteristics equivalent to those in the first and second embodiments. In the technique according to the third embodiment, a plurality of elongated electrodes each having a size, for example, of 200 cm×10 cm, may be arranged to increase an film-depositing area and reduce a volume of gas to be used, so as to achieve a film-deposition rate of 0.3 nm/s.

### INDUSTRIAL APPLICABILITY

The present invention makes it possible to deposit a hydrogenated amorphous silicon thin film free from a light-induced degradation, through a plasma CVD process. This thin film can be used as a power generation layer of a solar cell to achieve a high-efficiency solar cell free from a light-induced degradation.

### BRIEF DESCRIPTION OF DRAWINGS

FIG. 1 is a schematic diagram showing a first apparatus for depositing an aSi:H thin film of the present invention.

FIG. 2 is a graph showing a relationship between a thermophoretic force to be exerted on large clusters, and a diffusion force.

FIG. 3 is a graph showing a relationship between a radius of a through-hole of an electrode and a large-cluster removal rate.

FIG. 4 is a graph showing characteristics of the a-Si:H thin film of the present invention.

FIG. 5 is a graph showing a light-irradiation-time dependence of an in-film defect density.

FIG. 6 is a graph showing respective in-film Si—H₂ bond densities in two a-Si:H thin films which have been deposited, respectively, on upstream and downstream sides of a perforated high-frequency electrode in the apparatus illustrated in FIG. 1.

FIG. 7 is a schematic diagram showing a second apparatus for depositing the a-Si:H thin film of the present invention.

FIG. 8 is a graph showing a relationship between a permeability rate of one grid plate of a cluster removal filter and a large-cluster removal rate.

FIG. 9 is a schematic diagram showing a third apparatus for depositing the a-Si:H thin film of the present invention.

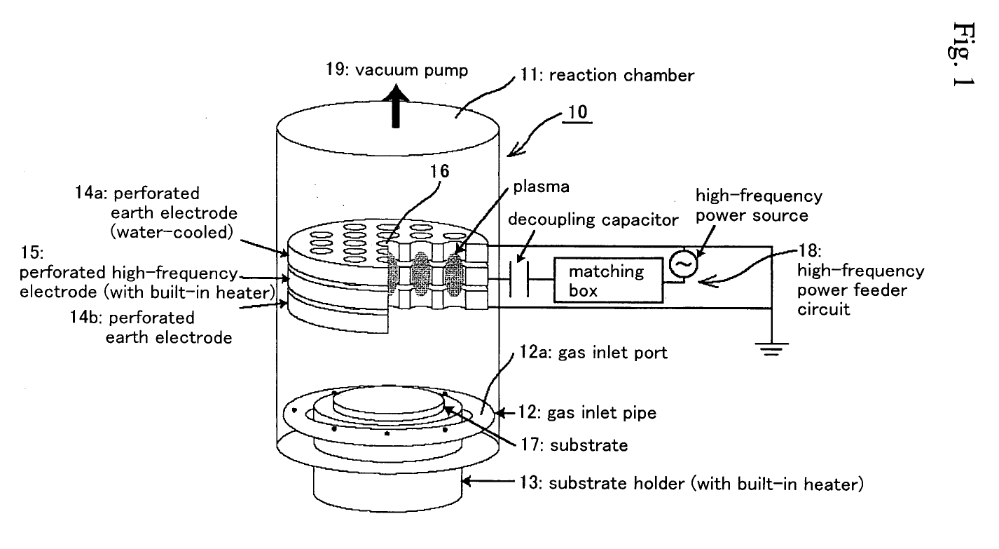

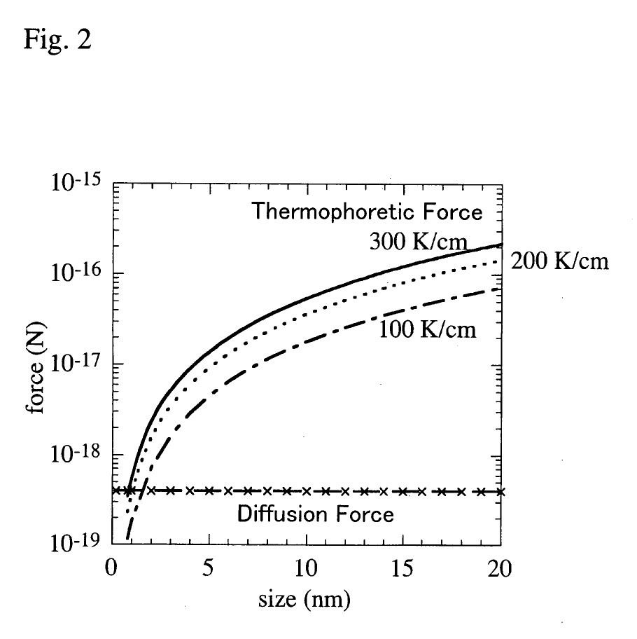

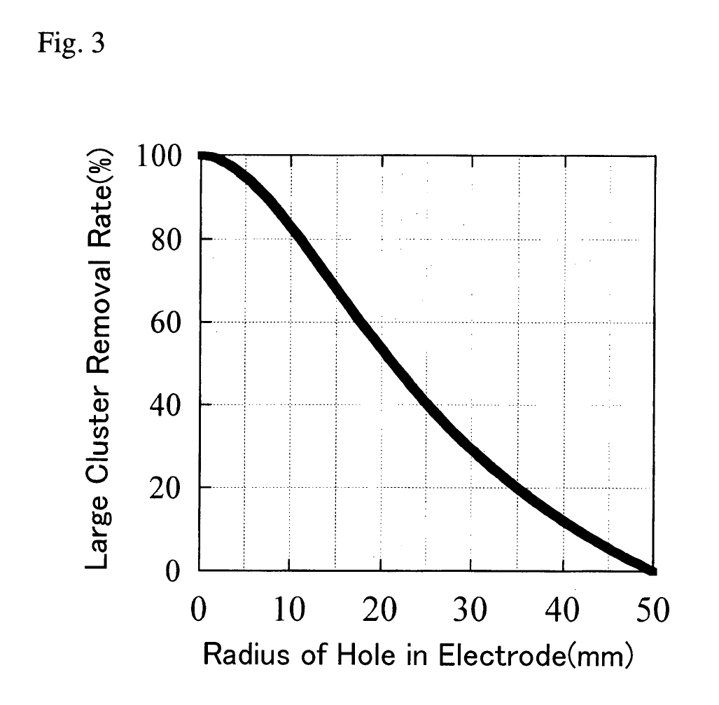

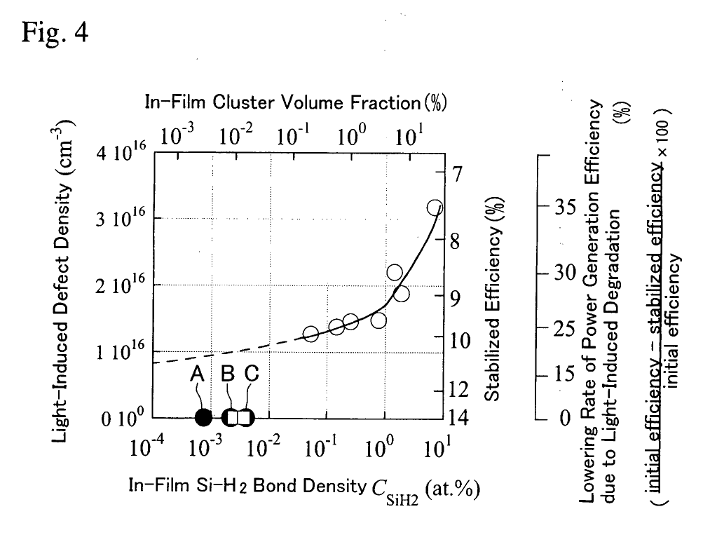

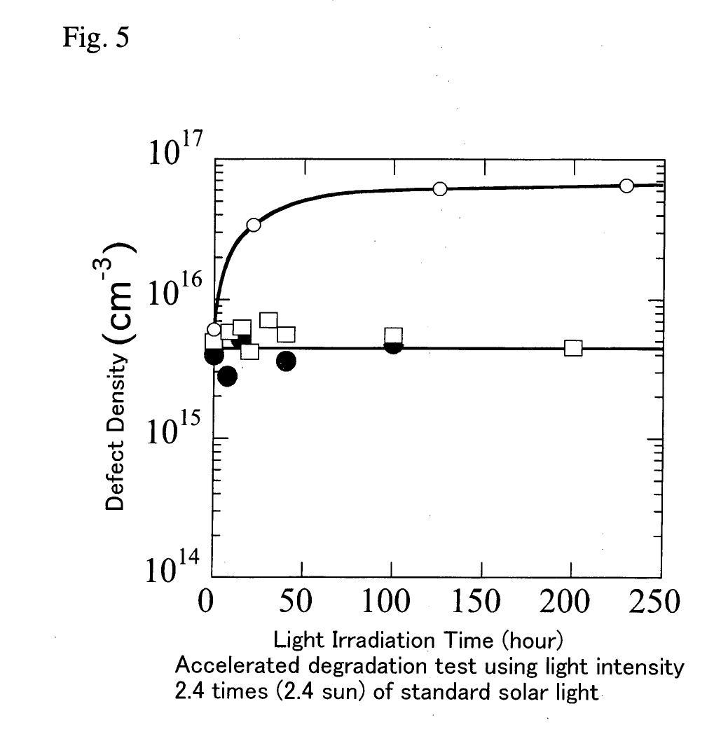

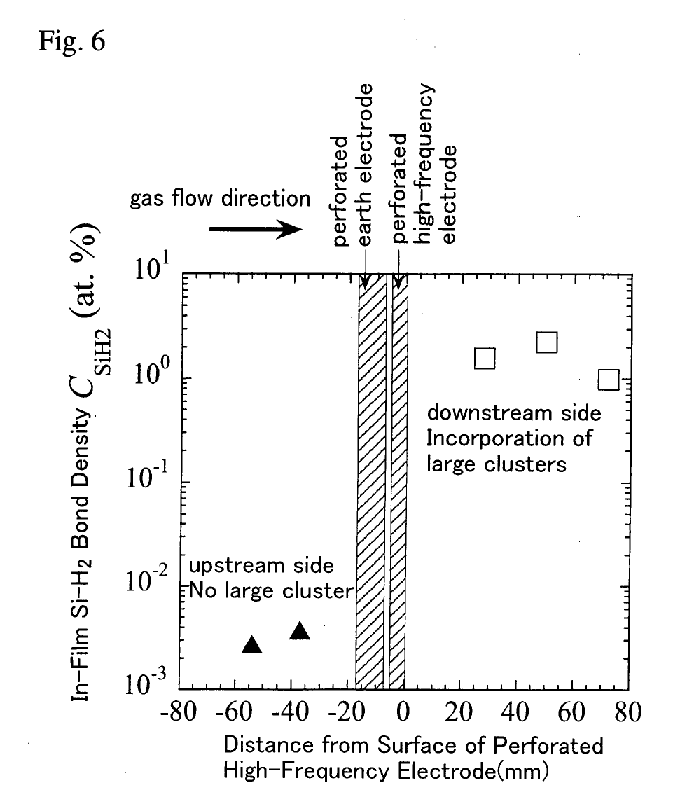

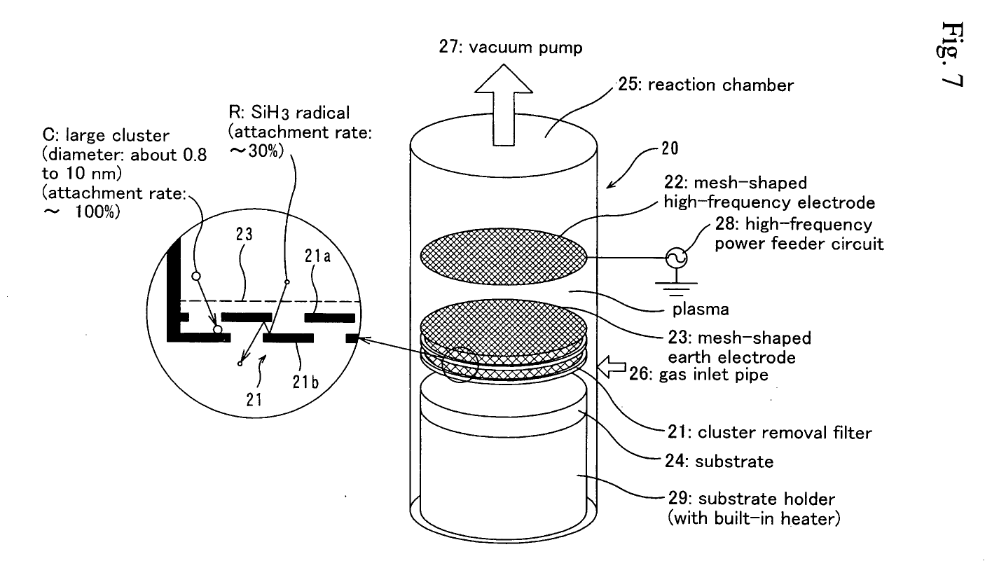

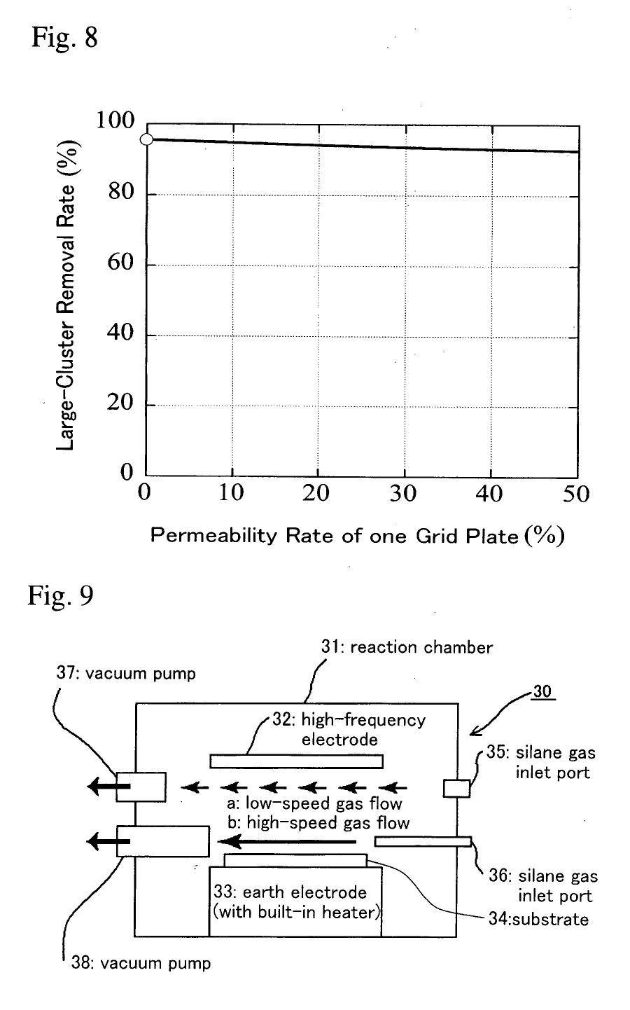

### DESCRIPTION OF THE REFERENCE NUMERALS AND SIGNS

10, 20, 30 amorphous silicon thin film deposition apparatus
11 reaction chamber
12 gas inlet pipe
12a gas inlet port
13 substrate holder
14a, 14b perforated earth electrode
15 perforated high-frequency electrode
16 through-hole
17 substrate
18 high-frequency power feeder circuit
19 vacuum pump
21 cluster removal filter
21a, 21b grid plate
22 mesh-shaped high-frequency electrode
23 mesh-shaped earth electrode
24 substrate
25 reaction chamber
26 gas inlet pipe
27 vacuum pump
28 high-frequency power feeder circuit
29 substrate holder
31 reaction chamber
32 high-frequency electrode
33 earth electrode
34 substrate
35, 36 silane gas inlet port
37, 38 vacuum pump

What is claimed is:

1. A cluster-free amorphous silicone film, wherein an in-film Si—H₂ bond density is 10⁻² atomic % or less, and an in-film volume fraction of large clusters having a size of 1 nm or more is 10⁻¹% or less.

2. The cluster-free amorphous silicone film as defined in claim 1, which comprises a Si film deposited on a substrate, a deposition material in a plasma flow of any one of a silane gas, a disilane gas and a gas obtained by diluting a silane or disilane gas with one or a combination of two or more selected from the group consisting of hydrogen, Ar, He, Ne and Xe.

3. The cluster-free amorphous silicone film as defined in claim 2, wherein a light-induced defect density is substantially zero cm⁻³.

4. A method in an apparatus designed such that a substrate, a mesh-shaped earth electrode and a mesh-shaped high-frequency electrode are disposed in a face-to-face arrangement within a vacuum chamber supplied with a gas containing a deposition material, wherein a high-frequency power generated by a high-frequency power feeder circuit is fed to said high-frequency electrode to create a plasma between said high-frequency electrode and said earth electrode so as to deposit said deposition material on said substrate to produce a cluster-free amorphous silicone film, said method comprising arranging a filter immediately above said substrate to remove large clusters in said plasma through said filter.

5. A method in an apparatus designed such that a substrate, a perforated high-frequency electrode and a perforated earth electrode are disposed in a face-to-face arrangement within a vacuum chamber supplied with a gas containing a deposition material, wherein a high-frequency power generated by a high-frequency power feeder circuit is fed to said perforated high-frequency electrode to create a plasma in respective holes of said perforated high-frequency electrode and said perforated earth electrode so as to deposit said deposition material on said substrate to produce a cluster-free amorphous silicone film, said method comprising:
directing a silane gas or a disilane gas to pass through the holes of said perforated high-frequency electrode and said perforated earth electrode from the side of said substrate;
generating a temperature gradient between said perforated high-frequency electrode and said perforated earth electrode so as to exert a thermophoretic force on large clusters in gaseous phase; and
capturing the large clusters by respective inner walls of the holes of said perforated high-frequency electrode and said perforated earth electrode to remove the large clusters.

6. A method in an apparatus designed such that a high-frequency electrode and a substrate supported by an earth electrode are disposed in a face-to-face arrangement within a vacuum chamber supplied with a gas containing a deposition material, wherein a high-frequency power generated by a high-frequency power feeder circuit is fed to said high-frequency electrode to create a plasma between said high-frequency electrode and said earth electrode so as to deposit said deposition material on said substrate to produce a cluster-free amorphous silicone film, said method comprising directing a high-speed silane gas or a high-speed disilane gas to flow between said high-frequency electrode and said substrate and along said substrate so as to form a gas curtain for preventing large clusters from being incorporated in the amorphous silicon film.

7. An apparatus designed such that a substrate, a mesh-shaped earth electrode and a mesh-shaped high-frequency electrode are disposed in a face-to-face arrangement within a vacuum chamber supplied with a gas containing a deposition material, and a high-frequency power generated by a high-frequency power feeder circuit is fed to said high-frequency electrode to create a plasma between said high-frequency electrode and said earth electrode so as to deposit said deposition material on said substrate to produce a cluster-free amorphous silicone film, said apparatus comprising a filter which is arranged immediately above said substrate and adapted to remove large clusters in said plasma.

8. An apparatus designed such that a substrate, a perforated high-frequency electrode and a perforated earth electrode are disposed in a face-to-face arrangement within a vacuum chamber supplied with a gas containing a deposition material, and a high-frequency power generated by a high-frequency power feeder circuit is fed to said perforated high-frequency electrode to create a plasma in respective holes of said perforated high-frequency electrode and said perforated earth electrode so as to deposit said deposition material on said substrate to produce a cluster-free amorphous silicone film, said apparatus comprising:
gas directing means adapted to direct a silane gas or a disilane gas to pass through the holes of said perforated high-frequency electrode and said perforated earth electrode from the side of said substrate; and
heating means adapted to heat said perforated high-frequency electrode so as to generate a temperature gradient between said perforated high-frequency electrode and said perforated earth electrode to exert a thermophoretic force on large clusters in gaseous phase.

9. An apparatus designed such that a high-frequency electrode and a substrate supported by an earth electrode are disposed in a face-to-face arrangement within a vacuum chamber supplied with a gas containing a deposition material, and a high-frequency power generated by a high-frequency power feeder circuit is fed to said high-frequency electrode to create a plasma between said high-frequency electrode and said earth electrode so as to deposit said deposition material on said substrate to produce a cluster-free amorphous silicone film, said apparatus comprising gas directing means adapted to direct a high-speed silane gas or a high-speed disilane gas to flow between said high-frequency electrode and said substrate and along said substrate.
